(19) United States
(12) Patent Application Publication
(10) Pub. No.: US 2014/0159558 A1
(43) Pub. Date: Jun. 12, 2014

(54) HOUSING WITH LATHCING MECHANISM

(71) Applicants: FU TAI HUA INDUSTRY (SHENZHEN) CO., LTD., Shenzhen (CN); HON HAI PRECISION INDUSTRY CO., LTD., New Taipei (TW)

(72) Inventor: GANG-HUA LIU, Shenzhen (CN)

(73) Assignees: HON HAI PRECISION INDUSTRY CO., LTD., New Taipei (TW); FU TAI HUA INDUSTRY (SHENZHEN) CO., LTD., Shenzhen (CN)

(21) Appl. No.: 13/831,885

(22) Filed: Mar. 15, 2013

(30) Foreign Application Priority Data
Dec. 7, 2012 (CN) 201210522016.X

(51) Int. Cl. H05K 5/02

(52) U.S. Cl. CPC H05K 5/0221
USPC 312/319.1

(57) ABSTRACT

A housing with latching mechanism includes a base, a cover, a number of latching members, and a plurality of resilient elements. The base includes a bottom plate and a sidewall protruding from the bottom plate. The cover includes a number of tabs each defining an engaging hole. The latching members are slidably connected to the sidewall of the base and each include a latching portion. The latching members are slidable between a first position where the latching portion is latchingly received in the engaging hole of the cover, thereby locking the cover to the base, and a second position where the latching portion disengages from the engaging hole of the cover, allowing the cover to be detached from the base. The resilient elements are used to apply a pushing force to the latching members for driving the latching members to move to the first position.

### BACKGROUND

1. Technical Field

The present disclosure relates to housings and, more particularly, to a housing utilizing a latching mechanism locking a base to a cover.

2. Description of Related Art

Portable electronic devices, such as mobile phones, include a housing for accommodating electronic components. Generally, the housing includes a base defining grooves and a cover with latches received in the grooves, which constitutes a latching mechanism for connecting the cover to the base. Although the latching mechanisms can satisfy basic requirements, an electronic device utilizing a new latching mechanism is still desired.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the present disclosure. Moreover, in the drawings, like reference numerals designate corresponding parts throughout the several views.

FIG. 1 is an isometric view of a housing with a cover and a latching mechanism according to an exemplary embodiment.

FIG. 2 is an isometric view of the housing of FIG. 1 with the cover detached.

FIG. 3 is an enlarged, isometric view of a portion of the housing of FIG. 2.

FIG. 4 is exploded, isometric view of the portion of FIG. 3.

FIG. 5 is a cross-sectional view of the housing, cutting along line V-V of FIG. 1.

### DETAILED DESCRIPTION

Embodiments of the present disclosure are now described in detail, with reference to the accompanying drawings.

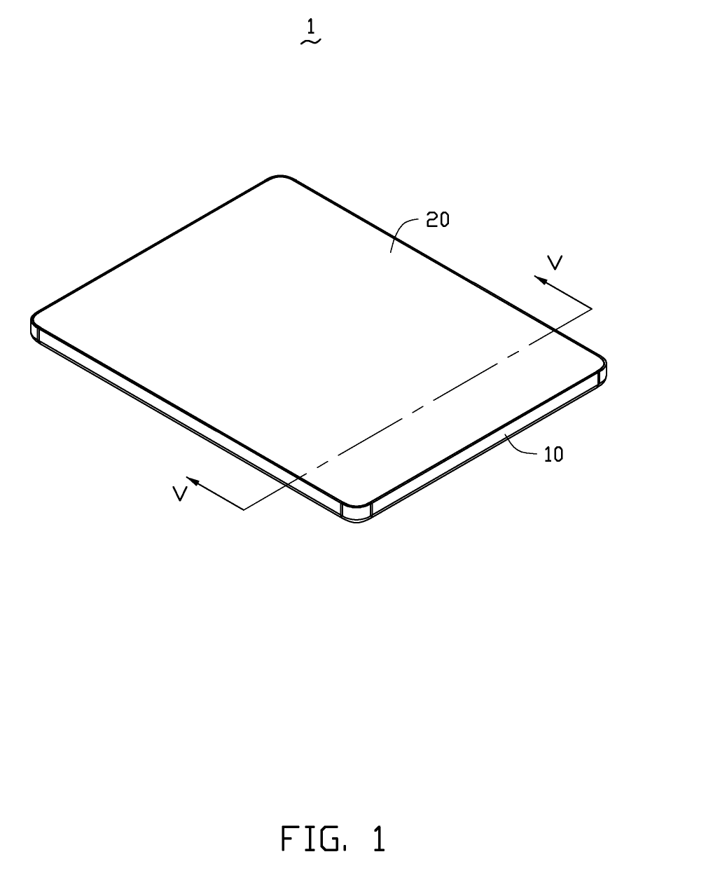

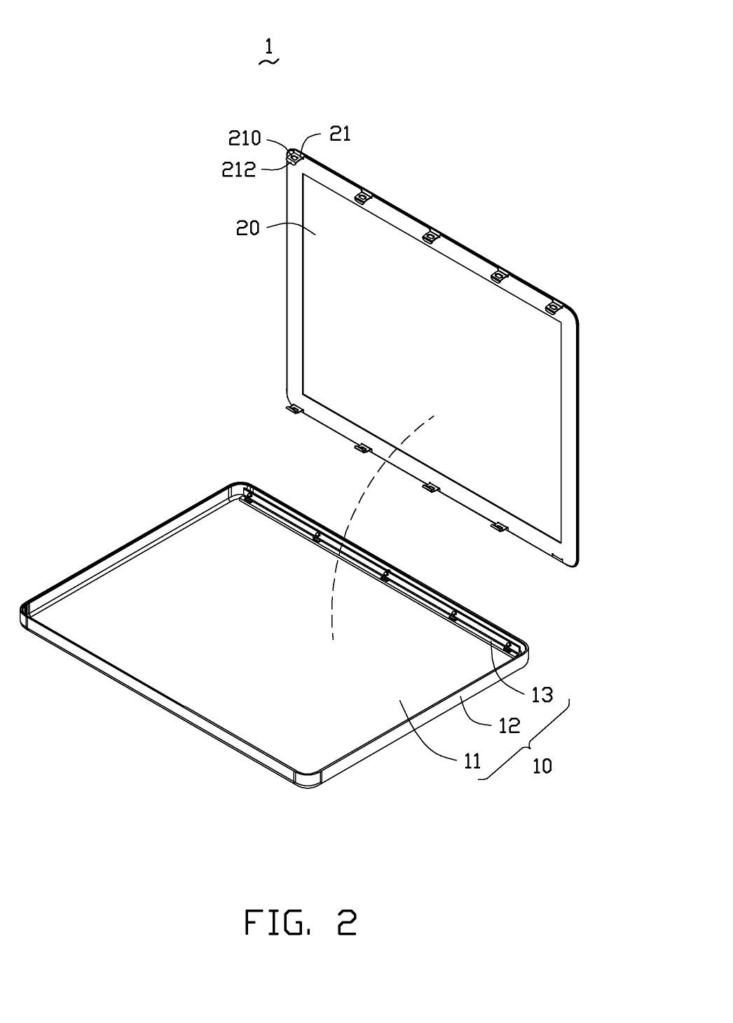

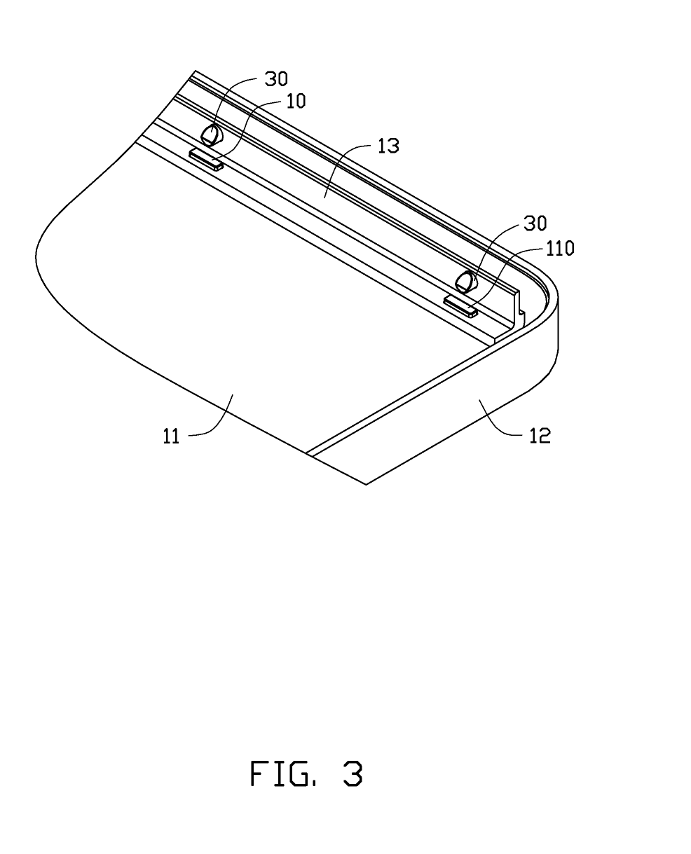

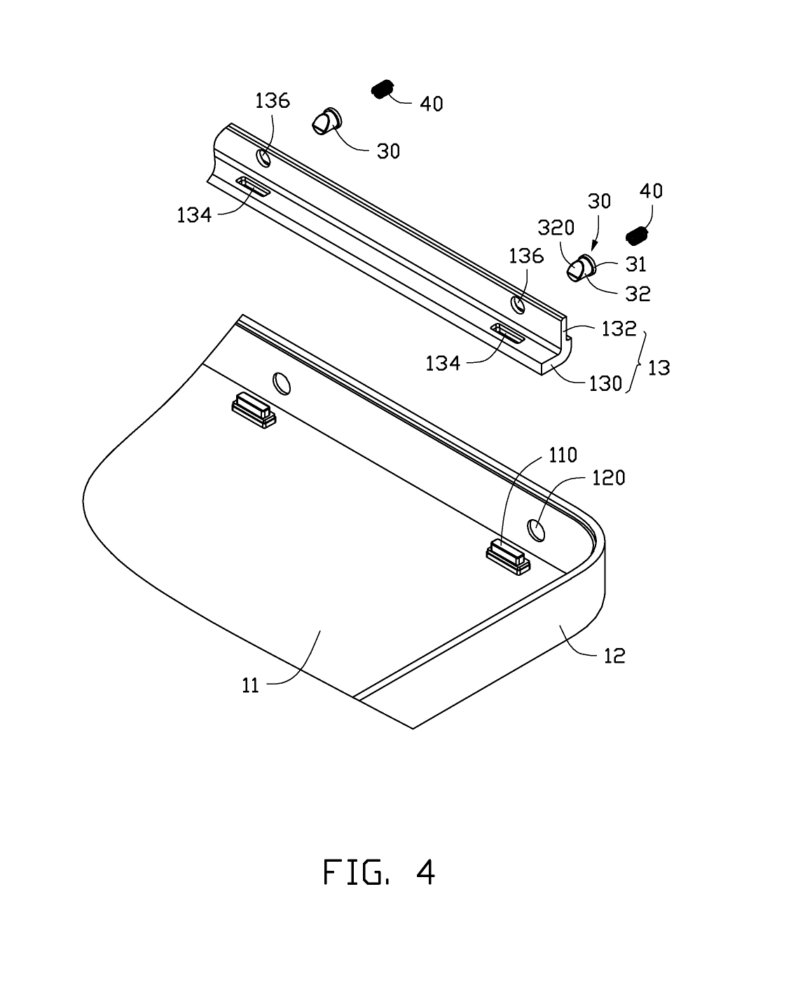

Referring to FIGS. 1-4, a housing 1 according to an exemplary embodiment is illustrated. The device housing 1 includes a base 10, a cover 20, a number of latching members 30, and a number of resilient elements 40. The base 10 and the cover 20 are coupled to each other and cooperatively define a receiving space (not labeled) therebetween for accommodating electronic components (not shown).

The base 10 includes a bottom plate 11, a sidewall 12 protruding from the bottom plate 11, and two support racks 13 located between the bottom plate 11 and the sidewall 12. The bottom plate 11 includes a number of spaced limiting portions 110 protruding therefrom. The limiting portions 110 may be made of resilient material, such as rubber. The sidewall 12 defines a number of first holes 120 corresponding to the limiting portions 110.

The support racks 13 each include a first plate 130 and a second plate 132 perpendicularly connected to each other. The first plate 130 is attached to the bottom plate 11 and defines a number of through holes 134 for the limiting portions 110 to extend therethrough. The second plate 132 is attached to the sidewall 12 and defines a number of slots 136.

The cover 20 includes a number of tabs 21 protruding perpendicularly from opposite edges thereof. The tabs 21 each define an engaging hole 210 and include a bent plate portion 212 parallel to the bottom plate 11.

Each latching member 30 includes a latching portion 32 extending through a corresponding one of the slots 136 of the support rack 13 and a head 31 formed at one end of the latching portion 32. The latching portions 32 are slidable in the slots 136 and include an end surface 320 inclined with respect to a sliding direction of the latching portion 32. The end surface 320 is facing toward the cover 20. When the cover 20 is coupled to the base 10, the tabs 21 contact the end surface 320 and drive the latching members 30 to move toward the sidewall 12. A diameter of the head 31 is greater than that of the slot 136, which prevents the latching member 30 from disengaging from the support rack 13. The latching member 30 further defines a second hole 33 aligned with a corresponding one of the first holes 120 of the sidewall 12.

The resilient elements 40 are used to apply a pushing force to the latching members 30, which pushes the latching portion 32 out of the slot 136. In the embodiment, the resilient elements 40 are spring coils with opposite ends retained in the corresponding first and second holes 120, 33.

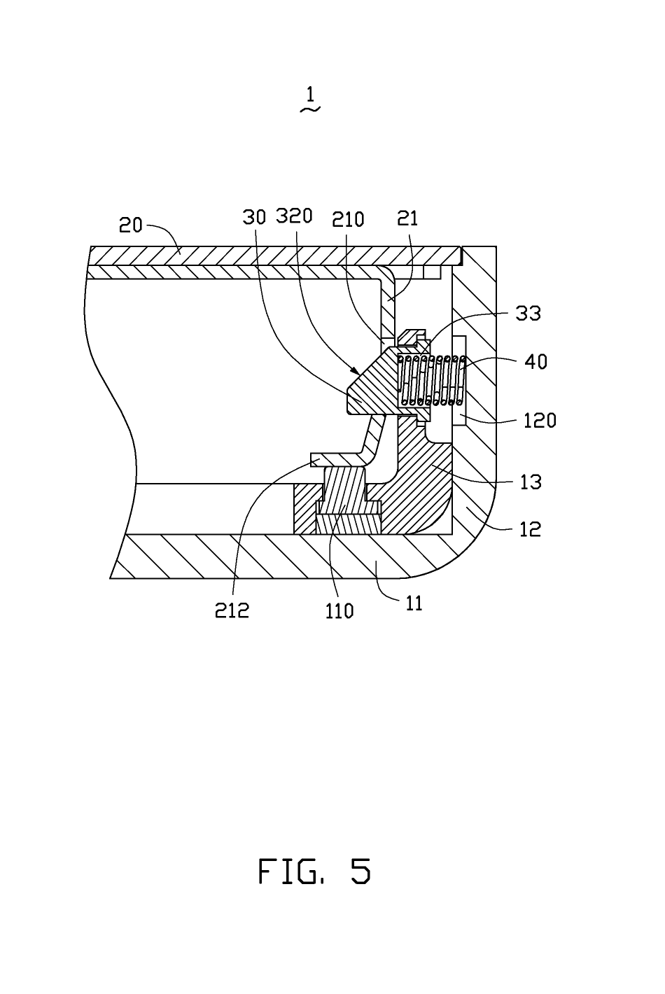

Referring to FIG. 5, the latching members 30 are latchingly received in the engaging holes 210 of the tabs 21, thereby locking the cover 20 to the base 10. The bent plate portion 212 abuts firmly against the limiting plate 110, thus preventing the tabs 21 from being elastically deformed by the latching members 30.

While various embodiments have been described and illustrated, the disclosure is not to be constructed as being limited thereto. Various modifications can be made to the embodiments by those skilled in the art without departing from the true spirit and scope of the disclosure as defined by the appended claims.

What is claimed is:

1. A housing with latching mechanism, comprising:
a base comprising a bottom plate and a sidewall protruding from the bottom plate;
a cover comprising a plurality of tabs, the plurality of tabs each defining an engaging hole;
a plurality of latching members slidably connected to the sidewall of the base, the plurality of latching members each comprising a latching portion, and being slidable between a first position where the latching portion is latchingly received in the engaging hole of the cover, thereby locking the cover to the base, and a second position where the latching portion disengages from the engaging hole of the cover, allowing the cover to be detached from the base; and
a plurality of resilient elements configured to apply a pushing force to the plurality of latching members for driving the plurality of latching members to move to the first position.

2. The housing with latching mechanism as described in claim 1, wherein the base further comprises a support rack comprising a first plate attached to the sidewall, the first plate defining a plurality of through holes for slidably retaining the plurality of latching members.

3. The housing with latching mechanism as described in claim 2, wherein each of the latching members comprises a head with a diameter greater than a size of the through hole, thereby preventing the latching member from sliding out of the corresponding through hole.

4. The housing with latching mechanism as described in claim 2, wherein the sidewall defines a plurality of first holes corresponding to the plurality of latching members, the plurality of latching members each define a second hole aligned with the corresponding first hole, and the resilient elements are spring coils with opposite ends respectively retained in the first holes and the second holes.

5. The housing with latching mechanism as described in claim 2, wherein each of the latching portions comprises an end surface inclined to a sliding direction of the latching member and facing toward the cover.

6. The housing with latching mechanism as described in claim 2, wherein each of the tabs comprises a bent plate portion parallel to the bottom plate, the base comprises a plurality of resilient limiting portion on the bottom plate, and when the latching portions of the plurality of latching members are latchingly received in the engaging holes of the plurality of tabs, the plurality of limiting portions abuts firmly against the bent plate portions of the plurality of tabs.

7. The housing with latching mechanism as described in claim 6, wherein the support rack further comprises a second plate attached to the bottom plate, the second plate defining a plurality of slots for extension of the limiting portions therethrough.
